(19) United States
(12) Patent Application Publication
(10) Pub. No.: US 2008/0196478 A1
(43) Pub. Date: Aug. 21, 2008

(54) Transition metals doped zeolites for saw based CO2 gas sensor applications

(75) Inventors: Raju A. Raghurama, Bangalore (IN); Sarin K. Anakkat Koyilothu, Bangalore (IN)

Correspondence Address: Bryan Anderson;Honeywell International Inc., 101 Columbia Rd., P.O. Box 2245, Morristown, NJ, 07962, US

(73) Assignee: Honeywell International Inc.

(21) Appl. No.: 11/708,902

(22) Filed: Feb. 20, 2007

(51) Int. Cl. G01N 29/02; H01L 41/22

(52) U.S. Cl. 73/24.06; 29/25.35

(57) ABSTRACT

A surface acoustic wave based CO₂ gas sensor that utilizes zeolites or transition metals doped zeolites as a sensing layer. Such zeolites can be used “as is” or doped with metal oxide semiconductor materials such as, for example, TiO₂, ZnO, SnO₂, electrolytes etc. to vary the sensor sensitivity for various gases. Zeolites can be configured as thin or thick films by employing nanopowders in suitable dispersants. The addition of zeolites, catalytically modified with chromium, results in a controlled selectivity to various gases based on shape and size effects.

### TECHNICAL FIELD

Embodiments are generally related to gas sensors. Embodiments are also related to acoustic wave devices and sensors. Embodiments are additionally related to acoustic wave based CO₂ gas sensors.

### BACKGROUND OF THE INVENTION

Gas sensors are needed to detect, measure and control gas concentrations in the context of, for example, exhaust emissions from various transport vehicles, oil fired furnaces, combustion processes, cabin air quality, air quality monitoring in air conditioned rooms and conference halls, and so forth. Metal oxide semiconductor and/or electrochemical based sensors are well developed for these purposes. Surface Acoustic Wave (SAW) based sensors, for example, are becoming popular because of their low power consumption, ease of fabrication and low cost to operate and produce.

Some SAW devices can function at elevated temperatures, which make these devices desirable for many applications. Acoustic wave sensors are so named because they use a mechanical or acoustic wave as the sensing mechanism. As the acoustic wave propagates through or on the surface of the material, any changes to the characteristics of the propagation path affect the velocity and/or amplitude of the wave.

The surface acoustic wave gas sensor uses a sensitive film coated on a sensitive substance which can readily absorb/adsorb the desirable substance to be detected. The sensitive film must possess a high sensitivity so as to be responsive to the presence of the substance, i.e., exhibit a low detection limit. Further, the sensitive film must retain its high sensitivity property relative to the gas to be detected, and it should also be able to detect the gas as quickly as possible.

Zeolites (or molecular sieves) or analogous molecular sieves show diverse chemical and physical properties depending on their chemical composition, structure, pre-treatment method, etc. A modified zeolite in which protons are replaced with other cations is widely used as a cracking catalyst of crude oil in the petrochemical industry, due to its resistance to high temperatures. Further, zeolites are widely used as a water-absorbing drying agent, adsorbent, gas-purifying agent, ion exchanger, additives for detergent, soil improving agent or the like.

In one prior art approach the synthesis of faujastic-Metglas composite material that can be used in gas sensing application is described. In this prior art continuous faujasite (large-pore zeolite) film was synthesized on a Metglas magneto elastic strip using secondary growth method. The ability of the composite to remotely sense carbon dioxide in nitrogen atmosphere at room temperature over a wide range of concentrations is demonstrated by monitoring the changes in the resonance frequency of the strip.

Zeolites can also be used to adsorb a particular gas species depending on the shape and size of the gas molecules. It is believed that the selectivity and sensitivity of zeolites can be improved by doping transition metals into the zeolite structure and thereby increase the catalytic activity for a particular gas.

### BRIEF SUMMARY

The following summary is provided to facilitate an understanding of some of the innovative features unique to the embodiments disclosed and is not intended to be a full description. A full appreciation of the various aspects of the embodiments can be gained by taking the entire specification, claims, drawings, and abstract as a whole.

It is, therefore, one aspect of the present invention to provide for an improved surface acoustic wave (SAW) based CO₂ gas sensor.

It is another aspect of the present invention to provide for a gas sensor with zeolites and/or zeolites doped into a metal oxide semiconductor as a sensing substrate.

It is a further aspect of the present invention to provide for a gas sensor with zeolites or a zeolite-based sensing substrate that is implemented as a thin or thick film.

The aforementioned aspects and other objectives and advantages can now be achieved as described herein. An acoustic wave gas sensor and a method of forming and operating the same are disclosed. In general, the acoustic wave gas sensor can be configured using a piezoelectric substrate. A pair of interdigital transducers can be configured upon the piezoelectric substrate. A gas sensitive layer can then be configured in association with the interdigital transducers upon the piezoelectric substrate from a plurality of zeolites and/or zeolites doped with transition metals, thereby providing the acoustic wave gas sensor. The pair of interdigital transducers can be arranged a comb-type configuration upon one side of the piezoelectric substrate. Additionally, a layer of nano-crystalline powders can be applied on the SAW devices such that the nano-crystalline powders of zeolites dispersed in a suitable solvent can form a coating on the SAW device formed on the piezoelectric substrate.

Zeolites can thus be utilized “as is” and/or doped into metal oxide semiconductor materials such as, for example, TiO₂, ZnO, SnO₂, and the like, in order to vary the sensitivity with respect to various gases. Zeolites can be made as thin or thick films by employing nanopowders in suitable dispersants. The addition of zeolites, catalytically modified with chromium, results in a controlled selectivity to alkanes based on shape and size effects. The cracking patterns of n-alkanes over Cr-zeolite Y and Cr-zeolite β between 200° C. and 400° C., for example, have been ascertained using a novel system involving a heated zeolite bed, thermal desorber and gas chromatography-mass spectrometry (GC-MS) The findings correlate with discrimination shown when the respective zeolites are incorporated as a catalytic layer on chromium titanium oxide (CTO) gas sensors used in a proprietary sensor array system to ascertain their suitability for inclusion into an electronic nose of a gas sensor.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein.

FIG. 1 illustrates a schematic diagram of a SAW based CO₂ sensor using zeolites and/or zeolites doped with transition metals in the context of a sensing layer, in accordance with a preferred embodiment;

FIG. 2 illustrates a cross-sectional view of an alternative SAW based CO₂ sensor, which can be implemented in accordance with an alternative embodiment; and

FIG. 3 illustrates a high level flowchart of operations depicting logical operational steps a method for the detection of CO₂ using a SAW based CO₂ sensor having zeolites or zeolites doped with transition metals in the context of sensing layer, in accordance with an alternative embodiment.

### DETAILED DESCRIPTION

The particular values and configurations discussed in these non-limiting examples can be varied and are cited merely to illustrate at least one embodiment and are not intended to limit the scope thereof.

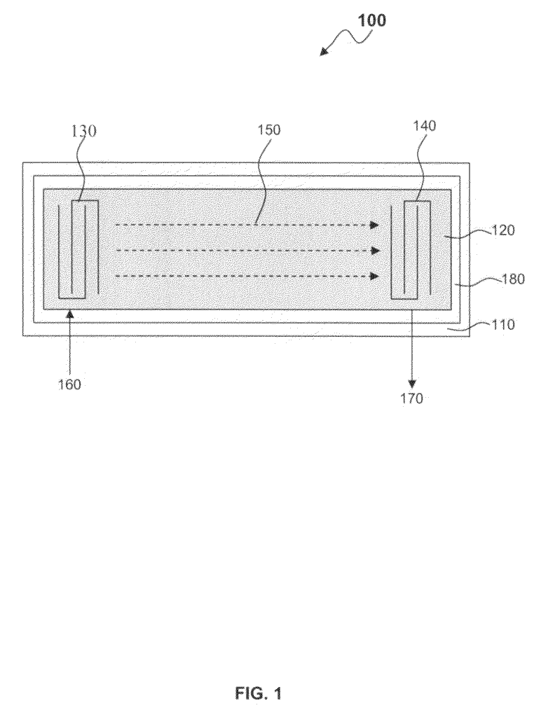

FIG. 1 illustrates a schematic diagram of a SAW-based CO₂ sensor 100, which includes the use of zeolites or zeolites doped with transition metals for use as a sensing layer in accordance with a preferred embodiment. The surface acoustic wave gas sensor (hereinafter referred to as “SAW gas sensor”) 100 includes a piezoelectric substrate 110 and, input interdigital transducer (hereinafter referred to as an “input IDT”) 130. SAW gas sensor 100 also includes an output interdigital transducer (hereinafter referred to as an “output IDT”) 140 and a gas sensing layer 120. A wave guiding layer 180 that functions as a dielectric layer can be fabricated onto the piezoelectric substrate 110 such that the input IDT 130 and output IDT 140 lie between the piezoelectric substrate 110 and wave guiding layer 180. The gas sensing layer 120 can be deposited onto the wave guiding layer 180 to form an active surface that can be exposed to gaseous media. SAW gas sensor 100 can thus be utilized to detect such gaseous media.

The piezoelectric substrate 110 can convert an electrical signal 160 into a mechanical surface acoustic wave 150, and then convert the surface acoustic wave 150 into an electrical signal 170 as depicted in FIG. 1. The input IDT 130 can transmit an electrical signal 160 to the piezoelectric substrate 110, and the output IDT 140 can transmit a transduced electrical signal 170 from the piezoelectric substrate 110 from the sensor 100 to an external receiver (not shown in FIG. 1). The input IDT 130 can be disposed on one side of the piezoelectric substrate 100, and the output IDT 140 can be disposed on the other side of the substrate 100. The input IDT 130 and the output IDT 140 can be preferably comb-patterned and spaced apart from each other, depending upon design considerations. The sensitive layer 120 can be composed of thin or thick films of zeolites or zeolites doped with transition metals such as, for example, Ti, V, Cr, Mn, Fe, Co, Ni and Cu. The sensitive layer 120 can be used to readily absorb/adsorb predetermined desirable gases.

By applying an alternating current (AC) voltage to the input IDT 130, an acoustic wave can be generated at the piezoelectric substrate 110. The acoustic wave can then be transmitted to the output IDT 140 through the surface of the piezoelectric substrate 110. When predetermined gases are absorbed/adsorbed on the sensitive layer 120, which is formed on the piezoelectric substrate 110 to increase the mass thereof, the frequency of the acoustic wave or amplitude of the acoustic wave150 can be varied to confirm whether a predetermined gas is present.

Generally, the types of substances utilized as the sensitive layer 120 can be variable with respect to the kinds of gases to be detected. In order to enable the SAW gas sensor 100 to detect CO₂, the sensitive layer 120 can be configured with zeolites or zeolites doped with transition metals. To improve the selectivity and also to improve the sensitivity of the sensor 100, transition metals can be doped into the Zeolite structure to increase the catalytic activity for a particular gas. Ti, V, Cr, Mn, Fe, Co, Ni and Cu can be selected, for example, to increase the selectivity with respect to different gases. The temperature of sensor 100 can be varied from an ambient temperature to, for example, approximately 400° C. to enhance the recovery time.

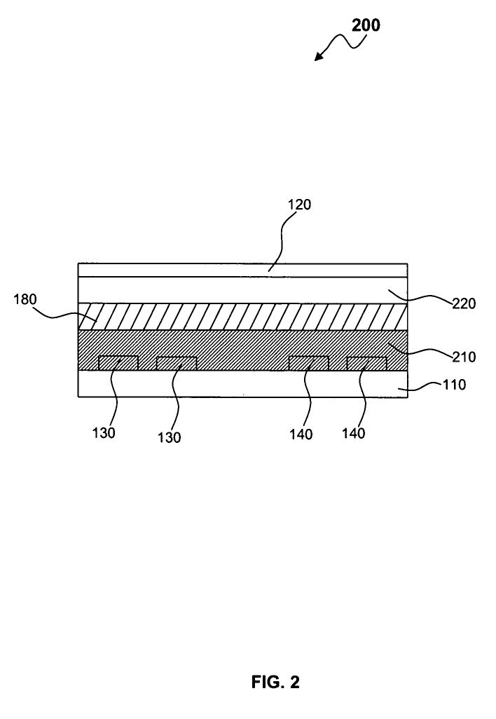

FIG. 2 illustrates a cross-sectional view of an alternative sensor embodiment, which is similar to the sensor 100 depicted in FIG. 1 except that a transitional layer 210 and a protecting layer 220 are also included in the alternative embodiment depicted in FIG. 2. Note that in FIGS. 1 and 2, identical or similar parts or elements are generally indicated by identical reference numerals. As indicated in FIG. 2, a SAW gas sensor 200 includes a transitional layer 210 that is preferably configured as an acoustically sensitive layer, which increases the velocity shift and as a result increases the electromechanical coupling factor. The transition layer 210 lies between the wave guiding layer 180 and the piezoelectric substrate 110 so that the distance between the first IDT 130 and a protective layer 220 is increased to facilitate a higher coupling coefficient and thereby reduce the acoustic wave transmission energy loss which would otherwise occur. The protective layer 220 lies between the sensitive layer 120 and the piezoelectric substrate 110 to protect the piezoelectric substrate 110 from damage.

The sensitive layer 120 can be provided with zeolites as thin and/or thick films, which can be configured by employing zeolites and/or zeolites doped with transition metals as nanopowders in a suitable dispersant. The addition of zeolites, catalytically modified with chromium, results in a controlled selectivity to alkanes based on shape and size effects. The cracking patterns of n-alkanes over Cr-zeolite Y and Cr-zeolite β between 200° C. and 400° C., for example, can be ascertained using a novel system involving a heated zeolite bed, thermal desorber and gas chromatography-mass spectrometry (GC-MS) GCMS is a method that combines the features of gas-liquid chromatography and mass spectrometry to identify different substances within a test sample. The findings correlate with a discrimination shown when the respective zeolites are incorporated as a catalytic layer in association with chromium titanium oxide (CTO) gas sensors. The experiment can be carried out with a proprietary sensor array system in order to ascertain their suitability for inclusion into an electronic nose.

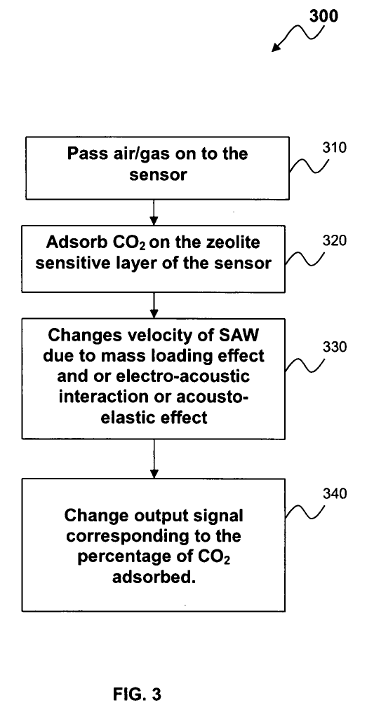

Referring to FIG. 3, a flowchart of operations is illustrated depicting logical operational steps of a method 300 for the detection of CO₂ using a SAW based CO₂ sensor (e.g., sensor 100 and/or 200), in accordance with an alternative embodiment. As indicated at block 310, gas or air can be passed on to the sensor 100 and/or 200. Next, as depicted at block 320, CO₂ present in the gas/air can be adsorbed on the sensitive layer of the sensor 100 and/or 200 via a zeolite and/or zeolite doped with transition metal substrate.

Next, as depicted at block 330, the velocity of the SAW traveling across the zeolite layer can be changed due to the mass loading effect and or electro-acoustic interaction or acousto-elastic effect that can be explained as follows. The gas absorbed by the sensitive layer increases the mass of the sensitive layer of sensor 100 and/or 200 and changes the wave frequency and/or attenuation. The change in frequency has been shown to be a direct function of the amount of gas absorbed/adsorbed. Finally, as depicted at block 340, an output signal can be changed corresponding to a percentage of CO₂ adsorbed/absorbed.

It will be appreciated that variations of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A method of forming an acoustic wave gas sensor, comprising:
providing a piezoelectric substrate;
forming a pair of interdigital transducers upon said piezoelectric substrate; and
configuring a gas sensitive layer in association with said pair of interdigital transducers upon said piezoelectric substrate from a plurality of zeolites, thereby providing an acoustic wave gas sensor for detecting a gas

2. The method of claim 1 further comprising configuring said pair of interdigital transducers in a comb-type configuration upon a side of said piezoelectric substrate.

3. The method of claim 1 further comprising applying a layer of nano-crystalline powders dispersed in a suitable solvent from said plurality of zeolites on said pair of interdigital transducers formed on said piezoelectric substrate.

4. The method of claim 1 wherein said plurality of zeolites comprises zeolites doped into at least one transition metal.

5. The method of claim 4 wherein said at least one transition metal comprises a metal oxide semiconductor material.

6. The method of claim 5 wherein said metal oxide semiconductor material comprises TiO₂.

7. The method of claim 5 wherein said metal oxide semiconductor material comprises ZnO.

8. The method of claim 5 wherein said metal oxide semiconductor material comprises SnO₂.

9. The method of claim 4 wherein said zeolites doped into said at least one transition metal are catalytically modified with said transition metals to selectively control various gases based on shape and size effects.

10. The method of claim 1 wherein said gas detectable by said acoustic wave gas sensor comprises CO₂.

11. An acoustic wave gas sensor, comprising:
a piezoelectric substrate;
a pair of interdigital transducers formed upon said piezoelectric substrate; and
a gas sensitive layer configured in association with said pair of interdigital transducers upon said piezoelectric substrate from a plurality of zeolites, thereby providing an acoustic wave gas sensor for detecting a gas.

12. The apparatus of claim 11 wherein said pair of interdigital transducers are arranged in a comb-type configuration upon a side of said piezoelectric substrate.

13. The apparatus of claim 11 further comprising a layer of nano-crystalline powders dispersed in a suitable solvent from said plurality of zeolites on said pair of interdigital transducers formed on said piezoelectric substrate.

14. The apparatus of claim 11 wherein said plurality of zeolites comprises zeolites doped into at least one transition metal.

15. The apparatus of claim 14 wherein said at least one transition metal comprises a metal oxide semiconductor material.

16. An acoustic wave gas sensor, comprising:
a piezoelectric substrate;
a pair of interdigital transducers formed upon said piezoelectric substrate, wherein said pair of interdigital transducers are arranged in a comb-type configuration upon a side of said piezoelectric substrate; and
a gas sensitive layer configured in association with said pair of interdigital transducers upon said piezoelectric substrate from a plurality of zeolites, thereby providing an acoustic wave gas sensor for detecting a gas.

17. The apparatus of claim 16 further comprising a transitional layer and a protection layer formed in association with said piezoelectric substrate.

18. The apparatus of claim 16 further comprising a layer of nano-crystalline powders dispersed in a suitable solvent from said plurality of zeolites on said pair of interdigital transducers formed on said piezoelectric substrate.

19. The apparatus of claim 17 wherein said plurality of zeolites comprises zeolites doped into at least one transition metal.

20. The apparatus of claim 19 wherein said at least one transition metal comprises a metal oxide semiconductor material.
